(19) United States
(12) Patent Application Publication
(10) Pub. No.: US 2026/0164711 A1
(43) Pub. Date: Jun. 11, 2026

(54) SPLIT GATE TRENCH STRUCTURE AND METHOD OF MANUFACTURING SAME

(71) Applicant: DB HiTek Co., Ltd., Bucheon-si (KR)

(72) Inventor: Han Seok KO, Bucheon-si (KR)

(21) Appl. No.: 19/050,120

(22) Filed: Feb. 11, 2025

(30) Foreign Application Priority Data
Dec. 9, 2024 (KR) 10-2024-0181300

(51) Int. Cl. H10D 30/66; H01L 21/02; H01L 21/311; H10D 30/01; H10D 64/27

(52) U.S. Cl. CPC H10D 30/668; H10D 30/0297; H10D 64/513; H10P 14/6308; H10P 50/283

(57) ABSTRACT

Proposed are a split gate trench structure and a method of manufacturing the same. More specifically, proposed are a split gate trench structure and a method of manufacturing the same, in which at least a side of an insulating film between a first poly region and a second poly region is formed to be surrounded by the second poly region, thereby preventing the first poly region and the second poly region from being interconnected and causing defects.

### CROSS REFERENCE TO RELATED APPLICATION

The present application claims priority to Korean Patent Application No. 10-2024-0181300, filed Dec. 9, 2024, the entire contents of which is incorporated herein for all purposes by this reference.

### BACKGROUND OF THE INVENTION

### Field of the Invention

The present disclosure relates generally to a split gate trench structure and a method of manufacturing the same. More specifically, the present disclosure relates to a split gate trench structure and a method of manufacturing the same, in which at least a side of an insulating film between a first poly region and a second poly region is formed to be surrounded by the second poly region, thereby preventing the first poly region and the second poly region from being interconnected and causing defects.

### Description of the Related Art

To address energy conservation, high-performance power MOSFETs are widely used in power electronics applications. The use of these high-performance power MOSFETs requires minimizing power loss. In order to minimize the power loss, it is essential to reduce switching loss and conduction loss of a device. The switching loss of a power MOSFET is determined by its gate charge. The conduction loss of the power MOSFET is determined by its on-resistance when the power MOSFET is turned on by applying voltage to a gate of the power MOSFET. For this reason, in order to reduce the switching loss of the power MOSFET, it is desirable to have a structure that can reduce the charge in a gate region.

In response to this, trench power MOSFETs, a type of power MOSFET, are being actively developed because they can secure high breakdown voltage and small drain-source resistance.

FIGS. 1A and 1B are sectional views each illustrating a conventional split gate trench structure. Hereinbelow, descriptions will be given of conventional split gate trench structures 9 and 9′and the problems arising therefrom.

With reference to FIG. 1A, a conventional split gate trench structure 9 is described. First, a shield electrode 930 and a gate electrode 940 are formed spaced apart from each other in the vertical direction in a trench 920 formed in a substrate 910 (or epitaxial layer). The shield electrode 930 has a structure in which it is surrounded by an insulating film 950 and split from the gate electrode 940. At this time, the insulating film 950 formed along an upper portion of the shield electrode 930 has an uneven thickness, which may deteriorate the gate oxide integrity (GOI) characteristics of a device.

Additionally, with reference to FIG. 1B, another conventional split gate trench structure 9′is described. An insulating film 950′having a relatively large thickness is formed between a shield electrode 930′and a gate electrode 940′. In order to form such a thick insulating film 950′between the shield electrode 930′and the gate electrode 940′, a gap-fill process for the insulating film 950′in a trench 920′, a CMP process for the insulating film 950′, and an etching process for the insulating film 950′in the trench 920′need to be performed after the formation of the shield electrode 930′. Therefore, these additional multiple processes may cause a problem of reducing the overall process efficiency.

In an effort to overcome the above problem, the inventors of the present disclosure have proposed a novel split gate trench structure, which will be described in detail later.

The foregoing is intended merely to aid in the understanding of the background of the present disclosure, and is not intended to mean that the present disclosure falls within the purview of the related art that is already known to those skilled in the art.

### DOCUMENTS OF RELATED ART

(Patent document 1) Korean Patent No. 10-1221242 “STRUCTURE AND METHOD FOR FORMING INTER-POLY DIELECTRIC IN A SHIELDED GATE FIELD EFFECT TRANSISTOR”

### SUMMARY OF THE INVENTION

Accordingly, the present disclosure has been made keeping in mind the above problems occurring in the related art, and one objective of the present disclosure is to provide a split gate trench structure and a method of manufacturing the same, in which at least a side of an insulating film between a first poly region and a second poly region is formed to be surrounded by the second poly region, thereby preventing the first poly region and the second poly region from being interconnected and causing defects.

Another objective of the present disclosure is to provide a split gate trench structure and a method of manufacturing the same, in which when forming an insulating film between a first poly region and a second poly region, a gap fill process, a CMP process, and an etching process for the insulating film are not required to be performed, thereby further improving the process efficiency.

Another objective of the present disclosure is to provide a split gate trench structure and a method of manufacturing the same, in which an intermediate insulating film with a substantially uniform thickness is formed on an upper portion of a first poly region, thereby improving the gate oxide integrity (GOI) characteristics.

Another objective of the present disclosure is to provide a split gate trench structure and a method of manufacturing the same, in which an oxide film is formed to have a narrow region with a relatively narrow horizontal width between an upper end and a lower end of the oxide film, thereby enabling easy formation of an intermediate insulating film in a subsequent process.

In order to accomplish the objectives of the present disclosure as described above and to carry out the characteristic functions of the present disclosure described below, embodiments of the present disclosure are described as follows.

According to one embodiment of the present disclosure, a split gate trench structure may include: a substrate; an epitaxial layer on the substrate; a trench extending downward from an upper surface of the epitaxial layer; an insulating film filling the trench; a first poly region surrounded by the insulating film within the insulating film; and a second poly region on the insulating film in the trench. The second poly region may have a lower surface that surrounds a side of the insulating film.

According to another embodiment of the present disclosure, the second poly region may have a recessed portion that is recessed upward from a side of the lower surface of the second poly region.

According to another embodiment of the present disclosure, the side of the insulating film may be filled in the recessed portion.

According to another embodiment of the present disclosure, the insulating film may have a tapered portion that becomes narrower in width as it extends upward from a side of a surface of the insulating film in contact with the lower surface of the first poly region.

According to another embodiment of the present disclosure, the tapered portion may be a polyoxide film.

According to another embodiment of the present disclosure, the tapered portion may be a film formed by performing a thermal oxidation process on a polysilicon film.

According to another embodiment of the present disclosure, the first poly region may have upper and lower portions having different curvatures.

According to another embodiment of the present disclosure, the upper portion of the first poly region may have a smaller curvature than the lower portion.

According to another embodiment of the present disclosure, the first poly region may have a maximum horizontal width in a range of greater than 0 to equal to or less than 0.15 μm.

According to another embodiment of the present disclosure, a split gate trench structure may include: a substrate; a trench extending downward from an upper surface of the substrate; a lower insulating film filling a lower portion of the trench; an intermediate insulating film on the lower insulating film in the trench; a first poly region having at least a side surrounded by the lower insulating film; an upper insulating film on the lower insulating film and the intermediate insulating film in the trench; and a second poly region on the upper insulating film in the trench. The intermediate insulating film may have a tapered portion that becomes narrower in width from a lower surface to an upper surface of the intermediate insulating film, and the second poly region may have a recessed portion that is recessed upward from a side of a lower surface of the second poly region and in which at least a side of the tapered portion is located.

According to another embodiment of the present disclosure, the lower insulating film may have an upper surface having a downward concave cross-sectional shape.

According to another embodiment of the present disclosure, the first poly region may have an upper end located within the intermediate insulating film.

According to another embodiment of the present disclosure, the first poly region may have an upper end located within the lower insulating film.

According to another embodiment of the present disclosure, the intermediate insulating film may have a vertical thickness in a range of greater than 0 to equal to or less than 2,000 Å.

According to another embodiment of the present disclosure, the lower insulating film may have a side in contact with the intermediate insulating film.

According to another embodiment of the present disclosure, the upper insulating film may have a side in contact with the recessed portion.

According to another embodiment of the present disclosure, a method of manufacturing a split gate trench structure may include: forming a trench in a substrate; forming a dielectric layer along an inner wall of the trench; forming a first polysilicon film on the dielectric layer in the trench; etching the first polysilicon film so that an upper portion of the first polysilicon film is located in the trench; etching the dielectric layer to expose sidewalls of an upper portion of the first polysilicon film; forming a silicon oxide film on the upper portion by performing a thermal oxidation process on the exposed upper portion of the first polysilicon film, and forming a first poly region; forming a first insulating film by performing an etching process on the silicon oxide film of the upper portion; forming a second insulating film on the first insulating film in the trench; and forming a second poly region on the second insulating film in the trench.

According to another embodiment of the present disclosure, a narrow region having a relatively narrow horizontal width may be formed in the first polysilicon film between upper and lower ends of the exposed upper portion of the first polysilicon film during the thermal oxidation process on the exposed upper portion of the first polysilicon film.

According to another embodiment of the present disclosure, the forming of the first insulating film may include: removing the silicon oxide film above the narrow region by performing an etching process. The first insulating film may have a shape in which a side of the upper surface thereof protrudes to become narrower in width upward.

According to another embodiment of the present disclosure, the removing of the silicon oxide film may be performed through a wet etching process.

The present disclosure has the following effects by the above configuration.

According to the present disclosure, by forming the at least the side of the insulating film between the first poly region and the second poly region to be surrounded by the second poly region, it is possible to prevent the first poly region and the second poly region from being interconnected and causing defects.

Additionally, according to the present disclosure, when forming the insulating film between the first poly region and the second poly region, by not requiring the gap fill process, the CMP process, and the etching process for the insulating film to be performed, it is possible to further improve the process efficiency.

Additionally, according to the present disclosure, by forming the intermediate insulating film with the substantially uniform thickness on the upper portion of the first poly region, it is possible to improve the gate oxide integrity (GOI) characteristics.

Additionally, according to the present disclosure, by forming the oxide film to have the narrow region with the relatively narrow horizontal width between the upper end and the lower end of the oxide film, it is possible to enable easy formation of the intermediate insulating film in the subsequent process.

Meanwhile, the effects of the present disclosure are not limited to the effects described above and other effects not stated directly could be understood from the following description and claims.

### BRIEF DESCRIPTION OF THE DRAWINGS

The above and other objectives, features, and other advantages of the present disclosure will be more clearly understood from the following detailed description when taken in conjunction with the accompanying drawings, in which:

FIGS. 1A and 1B are sectional view each illustrating a conventional split gate trench structure;

FIG. 2 is a sectional view illustrating a split gate trench structure according to an embodiment of the present disclosure; and

FIGS. 3 to 12 are sectional views illustrating a method of manufacturing a split gate trench structure according to an embodiment of the present disclosure.

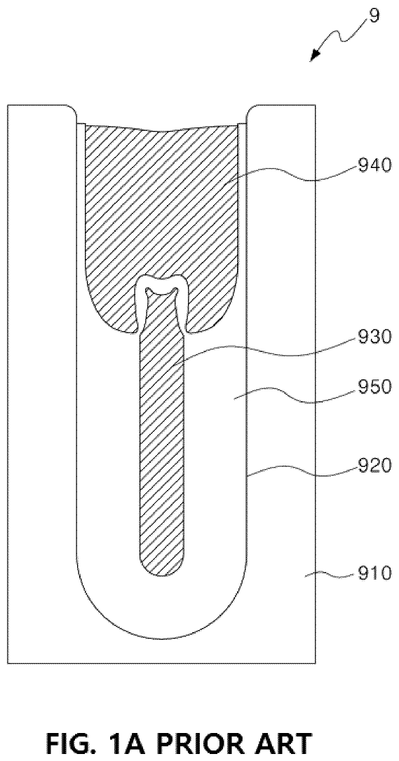

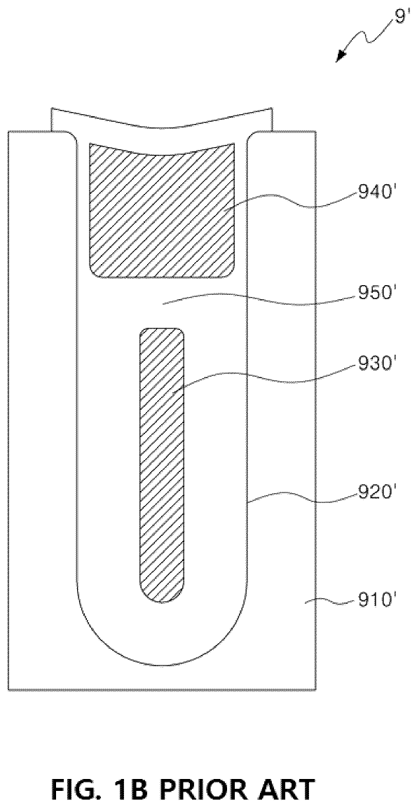

### DETAILED DESCRIPTION OF THE INVENTION

Hereinafter, exemplary embodiments of the present disclosure will be described in more detail with reference to the accompanying drawings. The embodiments of the present disclosure can be modified in various forms. Therefore, the scope of the present disclosure should not be construed as being limited to the following embodiments, but should be construed on the basis of the descriptions in the appended claims. The embodiments of the present disclosure are provided for complete disclosure of the present disclosure and to fully convey the scope of the present disclosure to those ordinarily skilled in the art.

As used herein, when an element (or layer) is referred to as being disposed on another element (or layer), it can be disposed directly on the other element, or intervening element(s) (or layer(s)) may be disposed therebetween. In contrast, when an element is referred to as being directly disposed on or above another element, intervening element(s) may not be located therebetween. Further, the terms “on”, “above”, “below”, “upper”, “lower”, “one side”, “side surface”, etc. are used to describe one element's relationship to another element(s) illustrated in the drawings.

While the terms “first”, “second”, etc. may be used herein to describe various items such as various elements, regions and/or parts, these items should not be limited by these terms.

When a certain embodiment may be implemented differently, a specific process order may be performed differently from the described order. For example, two consecutively described processes may be performed substantially at the same time or performed in an order opposite to the described order.

Additionally, a conductivity type or doped region of elements may be defined as “P-type” or “N-type” according to the main carrier characteristics. However, this is only for convenience of description, and the technical spirit of the present disclosure is not limited to the above-mentioned examples. For example, “P-type” or “N-type” will be used hereinafter as the more general terms “first conductivity type” or “second conductivity type”. Here, the first conductivity type may mean the P type and the second conductivity type may mean the N type, or conversely, the first conductivity type may mean the N type and the second conductivity type may mean the P type.

It should be further understood that the terms “heavily doped” and “lightly doped” representing the doping concentration of an impurity region mean the relative doping concentrations of elements.

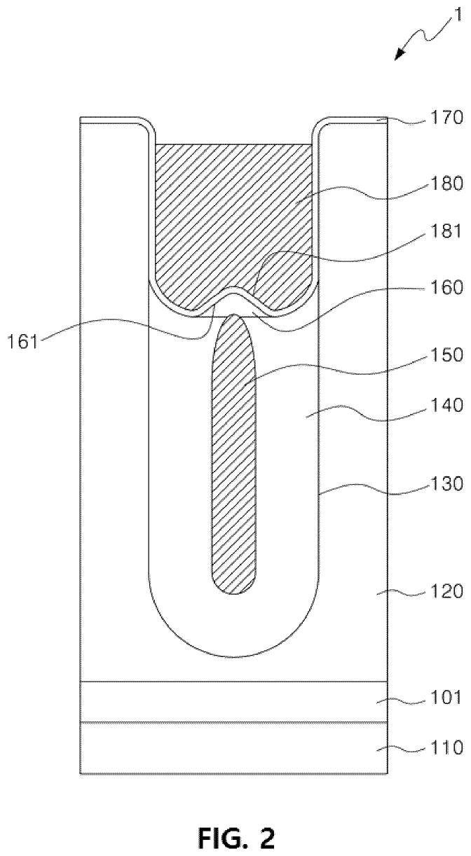

FIG. 2 is a sectional view illustrating a split gate trench structure 1 according to an embodiment of the present disclosure.

Hereinafter, the split gate trench structure 1 according to the embodiment of the present disclosure will be described in detail with reference to the attached drawings.

Referring to FIG. 2, the present disclosure relates generally to a split gate trench structure 1. More specifically, the present disclosure relates to a split gate trench structure 1, in which at least a side of an insulating film between a first poly region and a second poly region is formed to be surrounded by the second poly region, thereby preventing the first poly region and the second poly region from being interconnected and causing defects.

The split gate trench structure 1 according to the embodiment of the present disclosure may first include a substrate 101. The substrate 101 may be, for example, a silicon substrate. A drain electrode 110 may be formed on a lower surface of the substrate 101. An epitaxial layer 120 may be formed on the substrate 101. The epitaxial layer 120 may be, for example, a second conductivity type lightly doped impurity region.

A trench 130 may be formed to extend downward from an upper surface of the epitaxial layer 120 to a predetermined depth. While the trench 130 extends downward from the upper surface of the epitaxial layer 120 to the predetermined depth, a bottom portion of the trench 130 may be formed within the epitaxial layer 120 or within the substrate 101, but there are no particular limitations on the location thereof. A lower insulating film 140 may be formed in a lower portion of the trench 130 along inner sidewalls and a bottom surface of the trench 130. It is preferable that an upper surface of the lower insulating film 140 has a downward concave cross-sectional shape. Additionally, the upper surface of the lower insulating film 140 may be formed in a curved shape. Opposite sides of the upper surface of the lower insulating film 140 may be in contact with the upper insulating film 170 and an approximate central side thereof may be in contact with an intermediate insulating film 160.

The lower insulating film 140 may be, for example, a silicon oxide film, but the scope of the present disclosure is not limited by the above example. Hereinafter, in some cases, the lower insulating film 140 and the intermediate insulating film 160 are collectively referred to as a “first insulating film”, the upper insulating film 170 is referred to as a “second insulating film”, and the first insulating film and the second insulating film are collectively referred to as an “insulating film”. Further, in some cases, the substrate 101 is hereinafter understood as including the epitaxial layer 120.

Next, a first poly region 150 may be formed within the lower insulating film 140. The first poly region 150 may be formed in the lower portion of the trench 130 at an approximately central side of the trench 130 along the horizontal direction. For example, the first poly region 150 may have a lower surface and side walls surrounded by the lower insulating film 140, and an upper surface surrounded by the lower insulating film 140 or the intermediate insulating film 160. Lower and upper portions of the first poly region 150 may have different curvatures. For example, the lower portion of the first poly region 150 may have a greater curvature than the upper portion thereof, so the upper portion of the first poly region 150 may have a relatively sharp tip shape.

Additionally, the first poly region 150 may be, for example, a polysilicon film, and preferably has a maximum horizontal width set in a range of greater than 0 to equal to or less than 0.15 μm. When the maximum horizontal width of the first poly region 150 exceeds 0.15 μm, a smooth thermal oxidation process for a first polysilicon film P1, which will be described later, may not be guaranteed. The first poly region 150 may serve as a shield electrode.

Additionally, the intermediate insulating film 160 may be formed on the lower insulating film 140 in the trench 130. The intermediate insulating film 160 may be located on an upper portion of the first poly region 150, but it is preferable that the intermediate insulating film 160 is formed in a shape that surrounds the upper portion of the first poly region 150. That is, in some cases, the intermediate insulating film 160 may have a side located at substantially the same depth as the upper portion of the first poly region 150 within the epitaxial layer 120.

The intermediate insulating film 160 may be a region where the upper portion of the first poly region 150 is grown as a silicon oxide film through a thermal oxidation process. Additionally, the intermediate insulating film 160 may be formed between the lower insulating film 140 and the second poly region 180.

At this time, it is preferable that the intermediate insulating film 160 is formed with a cross-sectional shape having a side whose horizontal width becomes narrower from a lower surface to an upper surface of the intermediate insulating film 160, and it is more preferable that the intermediate insulating film 160 is formed with a horizontal width that becomes narrower from the lower surface to the upper surface. Accordingly, the intermediate insulating film 160 may have a tapered portion 161. The intermediate insulating film 160 may be, for example, a silicon oxide film, but the scope of the present disclosure is not limited by the above example. Additionally, the intermediate insulating film 160 may be formed on the lower insulating film 140 while having a vertical thickness in a range of equal to or less than 2,000 Å.

Next, an upper insulating film 170 may be formed in an upper portion of the trench 130 along the inner sidewalls of the trench 130 and an upper surface of the first insulating film. For example, the upper insulating film 170 may be formed substantially conformally, but the scope of the present disclosure is not limited thereto. Additionally, the upper insulating film 170 may have a cross-sectional shape corresponding to that of the intermediate insulating film 160 on the upper surface of the intermediate insulating film 160. That is, the upper insulating film 170 may be formed on the intermediate insulating film 160 in a shape that is recessed upward. The upper insulating film 170 may be, for example, an oxide film or a nitride film, but the scope of the present disclosure is not limited by the above examples. In FIG. 2, the upper insulating film 170 is illustrated as being thin, but it should be noted that the thickness thereof may vary.

The second poly region 180 may be formed on the upper insulating film 170 in the trench 130. The second poly region 180 is a region that fill the upper portion of the trench 130, and may be, for example, a polysilicon film. A lower surface of the second poly region 180 may have a recessed portion 181 that is recessed upward. For example, the second poly region 180 may have the recessed portion 181 in the trench 130 at the approximately central side of the trench 130 along the horizontal direction. In more detail, a side of each of the upper insulating film 170 and the intermediate insulating film 160 may be located inside the recessed portion 181. As described above, since the intermediate insulating film 160 has the tapered portion 161 whose width becomes narrower upward, the lower surface of the second poly region 180 where the tapered portion 161 is formed may be formed in a shape that is recessed upward. The second poly region 180 may serve as a gate electrode.

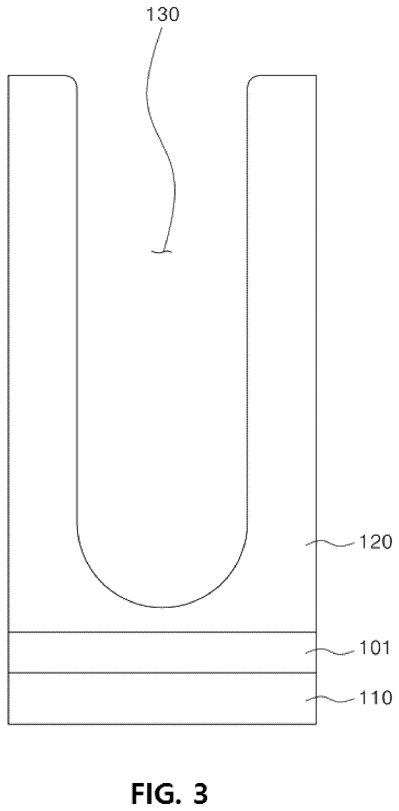

FIGS. 3 to 12 are sectional views illustrating a method of manufacturing a split gate trench structure according to an embodiment of the present disclosure.

Hereinafter, the method of manufacturing the split gate trench structure according to the embodiment of the present disclosure will be described in detail with reference to the attached drawings.

Referring to FIG. 3, first, a trench 130 may be formed in an epitaxial layer 120 formed on an upper surface of a substrate 101. The formation of the trench 130 may be achieved by forming a mask pattern (not illustrated) on the epitaxial layer 120 and then performing an etching process.

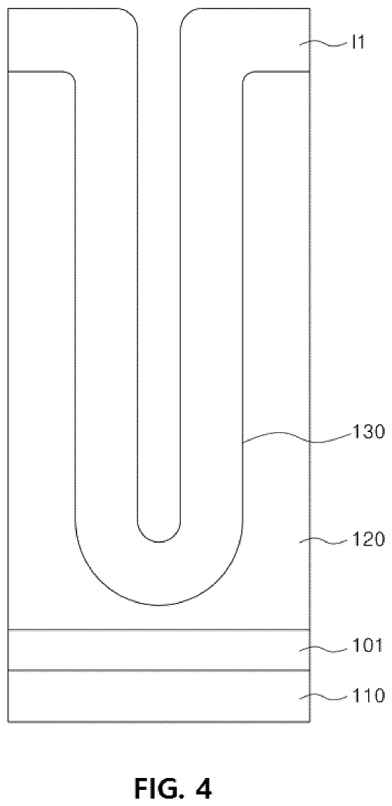

Referring to FIG. 4, a dielectric layer I1 may then be formed on an inner wall of the trench 130 and on the epitaxial layer 120. The formation of the dielectric layer I1 is preferably achieved by, for example, a thermal oxidation process, and more preferably by a wet oxidation process, but the scope of the present disclosure is not limited by the above processes. The dielectric layer I1 may be formed substantially conformally along the extension direction thereof.

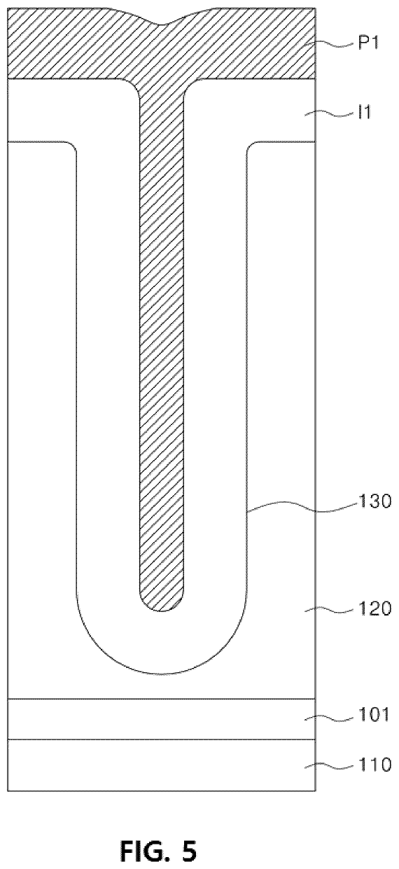

Referring to FIG. 5, a first polysilicon film P1 may then be formed on the dielectric layer I1. At this time, the first polysilicon film P1 may gap-fill the trench 130, and may also be formed on the dielectric layer I1 on an upper surface of the epitaxial layer 120.

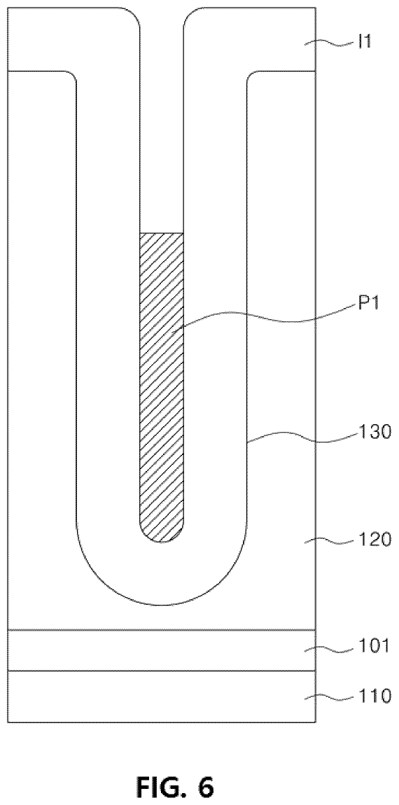

Referring to FIG. 6, the first polysilicon film P1 may then be etched. Through this process, the first polysilicon film P1 on the upper surface of the epitaxial layer 120 may be removed, and a part of the first polysilicon film P1 located in an upper portion of the trench 130 may be removed. As a result, the first polysilicon film P1 may have an upper surface located in the trench 130 and side walls surrounded by the dielectric layer I1.

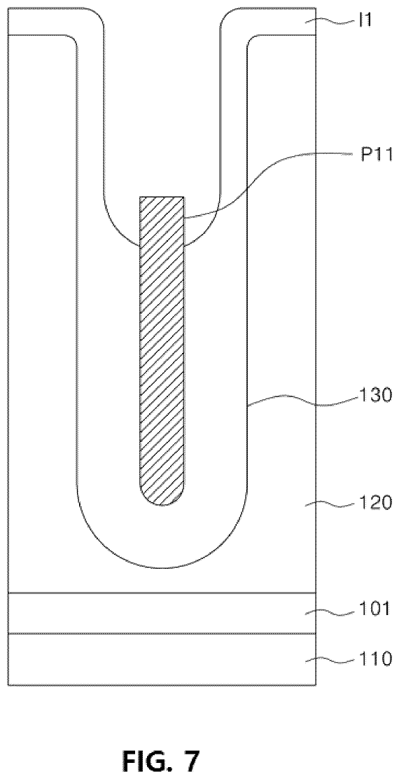

Referring to FIG. 7, an etching process may then be performed on the dielectric layer I1 to expose an upper portion P11 of the first polysilicon film P1. That is, sidewalls of the upper portion P11 of the first polysilicon film P1 may not surrounded by the dielectric layer I1. Additionally, when performing the etching process on the dielectric layer I1, the thickness of the dielectric layer I1 on the upper surface of the epitaxial layer 120 and inner sidewalls of the trench 130 may be reduced. For example, about 50% to 80% of the thickness of the dielectric layer I1 may be removed, thereby minimizing oxidation of inner sidewalls of the dielectric layer I1 remaining on the inner sidewalls of the trench 130 during a subsequent thermal oxidation process for the first polysilicon film P1.

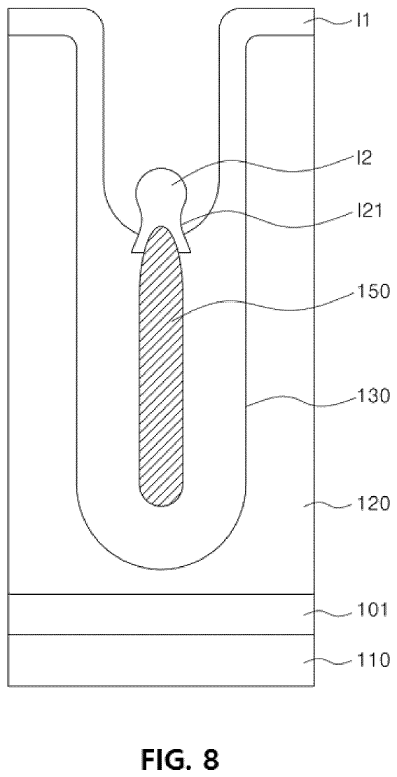

Referring to FIG. 8, a thermal oxidation process may then be performed on the exposed upper portion P11 (see FIG. 7) of the first polysilicon film P1 to remove the first polysilicon film P1 partially at the upper portion P11. During the thermal oxidation process on the upper portion P11 of the first polysilicon film P1, the oxidation rate of the first polysilicon film P1 may be faster than that of the dielectric layer I1, which is a silicon oxide film. Through this process, an oxide film I2 may be formed in an area from which the part of the first polysilicon film P1 has been removed. The oxide film I2 may be naturally formed thin at a side thereof adjacent to the dielectric layer I1. As a result, a narrow region I21 having a concave shape and a relatively narrow horizontal width may be formed in the oxide film I2 between upper and lower ends of the oxide film I2. Through this process, a first poly region 150 may be completed.

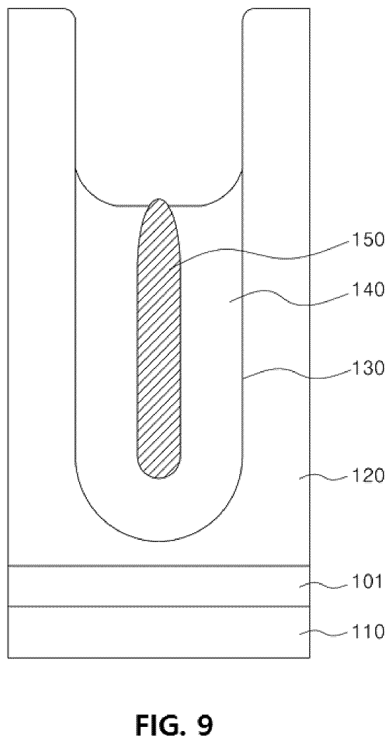

Referring to FIG. 9, an etching process may be performed on the dielectric layer I1 and the oxide film I2 in a subsequent process to complete a lower insulating film 140 and an intermediate insulating film 160. In detail, the dielectric layer I1 on the upper surface of the epitaxial layer 120 and the inner sidewalls of the trench 130 may be removed through the etching process to form the lower insulating film 140. Additionally, since the oxide film I2, which is a polyoxide film, has a faster wet etch rate than the dielectric layer I1 during the etching process for the oxide film I2, the oxide film I2 may be easy to remove. In particular, since the oxide film I2 has a narrow shape such as the narrow region I21, a side of the oxide film I2 may be easily removed. That is, as the narrow region I21 of the oxide film I2 is naturally cut, an area above the narrow region I21 and an area in the vicinity of the narrow region I21 may be removed. As a result, an upper portion of the first poly region 150 may be covered with a thin oxide film, which is a part of the oxide film I2, or the upper portion of the first poly region 150 may be slightly exposed as illustrated in FIG. 9.

As described above, in the formation of the intermediate insulating film 160, a process of gap-filling an insulating film on the lower insulating film 140 in the trench 130, a CMP process for the insulating film, and an etching process for an upper portion of the insulating film in the trench 130 may not be required, thereby further improving the process efficiency. Additionally, the intermediate insulating film 160 on the upper portion of the first poly region 150 may be formed with a substantially uniform thickness, thereby improving the gate oxide integrity (GOI) characteristics. That is, as the width of the upper portion of the first poly region 150 becomes narrower upward, the width of the intermediate insulating film 160 may also become narrower upward, so the thickness of the intermediate insulating film 160 on the upper portion of the first poly region 50 may be relatively uniform. Additionally, interconnection of the first poly region 150 and the second poly region 180 may be more reliably prevented by the formed intermediate insulating film 160.

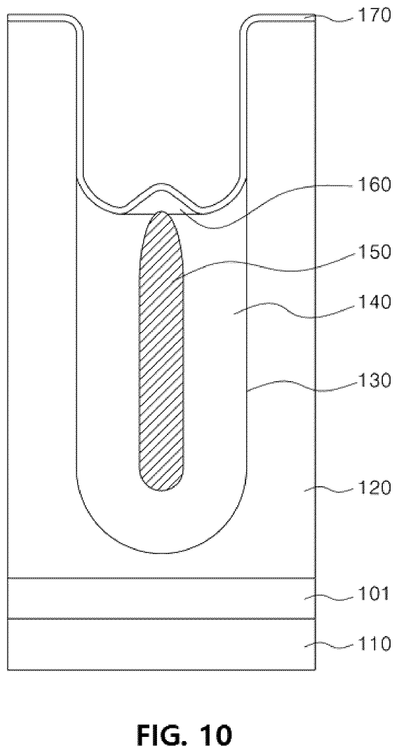

Referring to FIG. 10, an upper insulating film 170 or a second insulating film may then be formed on a first insulating film including the lower insulating film 140 and the middle insulating film 160 in the trench 130. The formation of the upper insulating film 170 may be achieved through a thermal oxidation process.

When performing a dry or wet oxidation process for forming the upper insulating film 170, the vicinity of the exposed upper portion of the first poly region 150 may be oxidized. As a result, an oxide film may be formed within the insulating film 140 and on the upper portion of the first poly region 150, thereby allowing an intermediate insulating film 160 to be formed. It is preferable that the oxidation process herein is a wet oxidation process, but the scope of the present disclosure is not limited thereto.

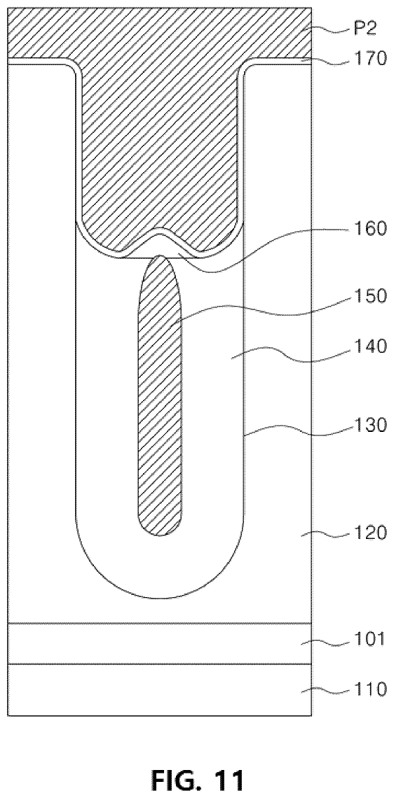

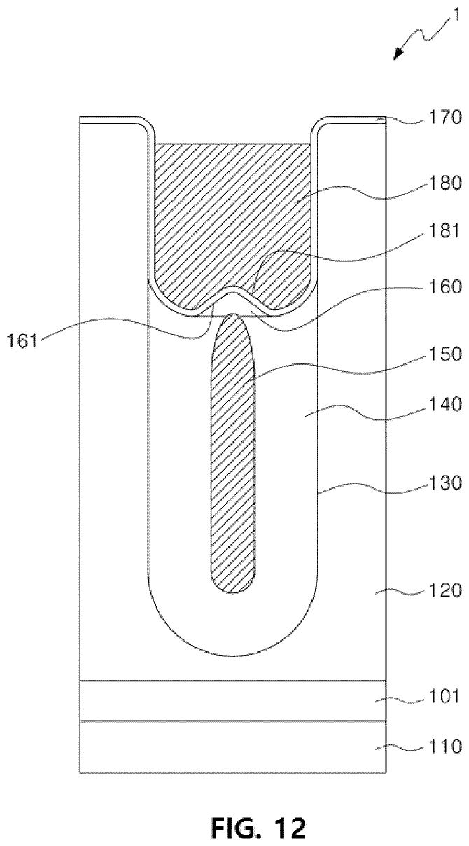

Then, a second poly region 180 may be formed in the trench T. This will be described in detail below. Referring to FIG. 11, first, a second polysilicon film P2 may be formed on the upper surface of the epitaxial layer 120 and on the upper insulating film 170 in the trench 130. Referring to FIG. 12, the second polysilicon film P2 on the upper surface of the epitaxial layer 120 may then be removed through, for example, a CMP process, to complete the second poly region 180.

The foregoing detailed description may be merely an example of the present disclosure. Also, the inventive concept is explained by describing the preferred embodiments and will be used through various combinations, modifications, and environments. That is, the inventive concept may be amended or modified without departing from the scope of the technical idea and/or knowledge in the art. The foregoing embodiments are for illustrating the best mode for implementing the technical idea of the present disclosure, and various modifications may be made therein according to specific application fields and uses of the present disclosure. Therefore, the foregoing detailed description of the present disclosure is not intended to limit the inventive concept to the disclosed embodiments.

What is claimed is:

1. A split gate trench structure, comprising:
a substrate;
an epitaxial layer on the substrate;
a trench extending downward from an upper surface of the epitaxial layer;
an insulating film in the trench;
a first poly region in and surrounded by the insulating film; and
a second poly region on the insulating film in the trench,
wherein the second poly region has a lower surface that surrounds a side of the insulating film.

2. The split gate trench structure of claim 1, wherein the second poly region has a recessed portion that is recessed upward from the lower surface of the second poly region.

3. The split gate trench structure of claim 2, wherein the side of the insulating film is in the recessed portion.

4. The split gate trench structure of claim 1, wherein the insulating film has a tapered portion that becomes narrower in width as it extends upward from a surface of the insulating film in contact with the first poly region.

5. The split gate trench structure of claim 4, wherein the tapered portion comprises a polyoxide film.

6. The split gate trench structure of claim 4, wherein the tapered portion comprises a thermal silicon oxide.

7. The split gate trench structure of claim 1, wherein the first poly region has an upper portion and a lower portion having different curvatures.

8. The split gate trench structure of claim 7, wherein the upper portion of the first poly region has a smaller curvature than the lower portion.

9. The split gate trench structure of claim 1, wherein the first poly region has a maximum horizontal width in a range of greater than 0 to equal to or less than 0.15 μm.

10. A split gate trench structure, comprising:
a substrate;
a trench extending downward from an upper surface of the substrate;
a lower insulating film in a lower portion of the trench;
an intermediate insulating film in the trench, on the lower insulating film;
a first poly region having at least a side surrounded by the lower insulating film;
an upper insulating film in the trench, on the lower insulating film and the intermediate insulating film; and
a second poly region in the trench, on the upper insulating film,
wherein the intermediate insulating film has a tapered portion that becomes narrower in width from a lower surface to an upper surface of the intermediate insulating film, and
the second poly region has a recessed portion that is recessed upward from a lower surface of the second poly region and that contains at least a side of the tapered portion.

11. The split gate trench structure of claim 10, wherein the lower insulating film has an upper surface having a concave cross-sectional shape.

12. The split gate trench structure of claim 10, wherein the first poly region has an upper end in the intermediate insulating film.

13. The split gate trench structure of claim 10, wherein the intermediate insulating film has a vertical thickness in a range of greater than 0 to equal to or less than 2,000 Å.

14. The split gate trench structure of claim 10, wherein the lower insulating film has a surface in contact with the intermediate insulating film.

15. The split gate trench structure of claim 10, wherein the upper insulating film has a surface in contact with the recessed portion.

16. A method of manufacturing a split gate trench structure, the method comprising:
forming a trench in a substrate;
forming a dielectric layer along an inner wall of the trench;
forming a first polysilicon film in the trench, on the dielectric layer;
etching the first polysilicon film so that an uppermost surface of the first polysilicon film is in the trench;
etching the dielectric layer to expose an upper portion of the first polysilicon film;
thermally oxidizing the exposed upper portion of the first polysilicon film to form a silicon oxide film on the upper portion of the first polysilicon film and a first poly region;
forming a first insulating film by etching the silicon oxide film on the upper portion of the first polysilicon film;
forming a second insulating film in the trench, on the first insulating film; and
forming a second poly region in the trench, on the second insulating film.

17. The method of claim 16, wherein while thermally oxidizing the exposed upper portion of the first polysilicon film, the silicon oxide film has a narrow region with a relatively narrow horizontal width between upper and lower ends of the silicon oxide film.

18. The method of claim 17, wherein forming the first insulating film comprises:
etching the silicon oxide film above the narrow region,
wherein the first insulating film has an upper surface that narrows in width as it protrudes upward.

19. The method of claim 18, wherein etching the silicon oxide film comprises wet etching.
